(19) United States
(12) Patent Application Publication
(10) Pub. No.: US 2015/0077951 A1
(43) Pub. Date: Mar. 19, 2015

(54) CIRCUIT BOARD ASSEMBLY

(71) Applicant: Novalia Ltd, Cambridge (GB)

(72) Inventor: Kate Stone, Cambridge (GB)

(21) Appl. No.: 14/382,516

(22) PCT Filed: Mar. 1, 2013
(86) PCT No.: PCT/GB2013/050517

§ 371 Date: Sep. 2, 2014

(30) Foreign Application Priority Data
Mar. 2, 2012 (GB) 1203726.3

(51) Int. Cl. H05K 1/14; H05K 1/18; H05K 1/11; H05K 1/03

(52) U.S. Cl. CPC H05K 1/147; H05K 1/144; H05K 1/0306; H05K 1/0393; H05K 1/181; H05K 1/111; H05K 2201/0314
USPC 361/750; 361/749

(57) ABSTRACT

A circuit board assembly is described. The circuit board assembly (1) comprises a module (2) which comprises a first flexible substrate (7) and a device mounted on the first flexible substrate and a circuit board (3) which comprises a second flexible substrate (4), wherein the module is mounted on the circuit board.

### FIELD OF THE INVENTION

The present invention relates to a circuit board assembly.

### BACKGROUND

Electronic components are increasingly being incorporated into printed articles, such as books, posters and greeting cards, to allow printed articles to become more interactive. Examples of interactive printed articles are described in GB 2 464 537 A, WO 2004 077286 A, WO 2007 035115 A and DE 1993 4312672 A.

Conventionally, discrete devices (such as capacitors) and packaged devices (such as microcontrollers) are mounted to a printed wiring board and the printed wiring board is mounted to or inserted into the printed article.

### SUMMARY

The present invention seeks to facilitate incorporation of devices into articles, such as games, books, greeting cards, product packaging and posters.

According to a first aspect of the present invention there is provided a module which comprises a first flexible substrate and a device mounted on the first flexible substrate and a circuit board which comprises a second flexible substrate, wherein the module is mounted on the circuit board.

Thus, not only can the device be packaged to form a module using a moving continuous sheet process or other high-volume process which can be carried out using printing and/or converting processes (such that as described in GB 2 472 047 A), but also the module can also be mounted to the printed article or a part of the printed article using the same or similar processes.

The device comprises a set of terminals. The set of terminals may be connected, for example bonded by conductive glue, ink or tape, to a first set of contact pads provided on the first flexible substrate. Some or all of the contact pads may be bigger than the terminals.

The first set of contact pads may be connected, for example bonded by conductive glue, ink or tape, to a second set of contact pads disposed on the second flexible substrate.

The first set of contacts may be disposed on a first face of the first flexible substrate and can serve not only as contact regions to the device, but also as contact regions to the circuit board. For example, the module may be mounted on the second flexible substrate in an inverted state (or “flipped”) in which the first set of contact pads face the second flexible substrate. Alternatively, portion(s) of the first substrate may be folded under the module such that part(s) of some or all of the first set of contacts face the second flexible substrate and the module may be mounted on the second flexible substrate in an upright state. The first flexible substrate may include cuts or slots, for example, extending from edges of the first substrate to allow or help some (but may be not other) parts of the first substrate to be folded.

The first set of contact pads may be connected to a third set of contact pads disposed on the first flexible substrate. Thus, the first set of contact pads can serve as contact regions to the device while the third set of contact pads electrically connected to the first set of contact pads serve as separate contact regions to the circuit board.

The third set of contact pads may be disposed on the first face of the first flexible substrate, but spaced apart from the first set of contact pads and be connected by conductive tracks. Thus, the third set of contact pads may be extensions of the first set of contact pads. For example, the first and third sets of contact pads and conductive tracks may be formed in the same layer of conductive material. Thus, the module may be mounted on the second flexible substrate in an inverted state or in an upright state with the third set of contact pads disposed on folded portions of the first flexible substrate.

The third set of contact pads may be disposed on a second, opposite face of the first flexible substrate.

The first and third sets of contact pads may be electrically connected using conductive glue or ink filling a via (or “hole”) passing between the first and second faces of the first flexible substrate. Additionally or alternatively, the first and third sets of contact pads may be connected using conductive glue, ink, tape or foil running from the first set of contacts on the first face, over one or more edges of the first flexible substrate and onto the first set of contacts on the second face.

The third set of contact pads may be connected, for example using conductive glue, ink or tape, to the second set of contact pads disposed on the second flexible substrate.

The second set of contact pads disposed on the second flexible substrate may be or be connected to a set of conductive tracks, for example, formed of conductive ink or foil.

The device may be interposed between the first and second flexible substrates. The first flexible substrate may be interposed between the device and the second flexible substrates.

The first flexible substrate may comprise paper, card, cardboard or other similar fibre-based material. The paper or card may comprise formable paper or card. The first flexible substrate may be shaped (or “moulded”). For example, the first flexible substrate may be embossed. The first flexible substrate may comprise plastic. For example, the substrate may comprise polyethylene terephthalate (PET), polypropylene (PP) or polyethylene naphthalate (PEN). The first flexible substrate may comprise a laminate, for example comprising a layer of fibre-based material covered with a layer of plastic or sandwiched between two layers of plastic. By using a fibre-based material, less material can be used which can be environmentally friendly. Fibre-based material may comprise recycled material.

The first and second flexible substrates may comprise substantially the same material(s).

The device may be mounted to the first flexible substrate using conductive glue, conductive ink or conductive tape. The conductive ink may include a non-conductive adhesive. The conductive ink or glue may be water based. The conductive ink or glue may be solvent based. The conductive ink may be curable, for example using ultraviolet (UV) light. The conductive ink or glue can take the form of paste, i.e. a conductive paste.

The first flexible substrate may have an area of no more than 200 cm² or no more than 10 cm² (for no more than the size of die or “chip”).

The second flexible substrate may comprise paper, card, cardboard or other similar fibre-based material. The paper or card may comprise formable paper or card. The second flexible substrate may be shaped (or “moulded”). For example, the second flexible substrate may be embossed. The second flexible substrate may comprise plastic. For example, the substrate may comprise polyethylene terephthalate (PET), polypropylene (PP) or polyethylene naphthalate (PEN). The second flexible substrate may comprise a laminate, for example comprising a layer of fibre-based material covered by a layer of plastic or sandwiched between two layers of plastic.

The module may be mounted to the second flexible substrate using conductive glue, conductive ink or conductive tape. The packaged device may be mounted to the second flexible substrate using conductive glue, conductive ink or conductive tape. The conductive ink may include a non-conductive adhesive. The conductive ink or glue may be water based. The conductive ink or glue may be solvent based. The conductive ink may be curable, for example using UV light.

A water-based conductive ink or glue may have an application viscosity between 90 to 300 centipoise (cP). A UV-cured conductive ink or glue may have an application viscosity of about 250 to 600 cP. A solvent-based conductive ink or glue may have an application viscosity of 100 to 500 cP.

A water- or solvent-based conductive ink may have a solid content of 15 to 80% solids by volume and/or up to 95% by weight. A UV-cured conductive ink may be considered effectively to be 100% by volume or weight.

Conductive ink or glue (for example the first and/or second contact pads and/or bonding material) may have a thickness of at least 1 μm or at least 2 μm. The conductive ink or glue may have a thickness of at least 5 μm or at least 10 μm. The conductive ink or glue may have a thickness no more than 100 μm or no more than 50 μm. The conductive ink or glue may have a thickness of no more than 20 μm or no more than 10 μm. Dry conductive ink, for example applied by flexography, may have a thickness of between 1 and 10 μm.

The second flexible substrate may have an area of at least 500 cm². Thus, the circuit board may have a large area, e.g. A4 size or larger.

The device may comprise a semiconductor die. The device may comprise a microcontroller. The device may comprise a light emitting diode.

The second flexible substrate may support one or more capacitive touch switches, for example in the form a finger-tip-sized (e.g. having an area of between 0.2 mm² to 2 mm²) and/or an array of touch electrodes for a touch panel. Thus, a microcontroller and other devices may be directly mounted or mounted via one or more other flexible substrates to form an enhanced printed matter (such as poster or greeting card) which a user can provide input using touch.

The module may comprise at least two devices mounted to the first flexible substrate, e.g. using respective modules. Additionally or alternatively, the module may comprise at least one further device mounted to a third flexible substrate mounted to the second flexible substrate.

The circuit board assembly may comprise a printed article or a part (such as a cover) of printed article. The printed article may be a greeting card, poster, book, product packaging, point of sale display, map or pamphlet.

The printed article or part of the printed article may provide the second flexible substrate. Conductive regions (such as conductive tracks) may be disposed on a first face of the second flexible substrate and printed indicia may be disposed on a second, opposite face of the second flexible substrate.

According to a second aspect of the present invention there is provided a method of manufacturing a circuit board assembly, the method comprising mounting a module on a circuit board, wherein module comprises a first flexible substrate and a device mounted on the first flexible substrate, and the circuit board comprises a second flexible substrate.

The method may comprise attaching the device to the first flexible substrate using conductive glue, ink or tape. The method may comprise placing the glue, ink or tape on contact pads on the first flexible substrate and bringing the device and the first flexible substrate into contact.

The method may comprise attaching the module to the second flexible substrate using conductive glue, ink or tape. The method may comprise placing the glue, ink or tape on contact pads on the first and/or second flexible substrate(s) and bringing the module and the second flexible substrate into contact.

### BRIEF DESCRIPTION OF THE DRAWINGS

FIG. 1 is a simplified, perspective view of part of flexible circuit board assembly;

FIG. 2 is a simplified, perspective view of a flexible module; and

FIG. 3 illustrates mounting the flexible module shown in FIG. 1 to a flexible circuit board.

### DETAILED DESCRIPTION OF CERTAIN EMBODIMENTS

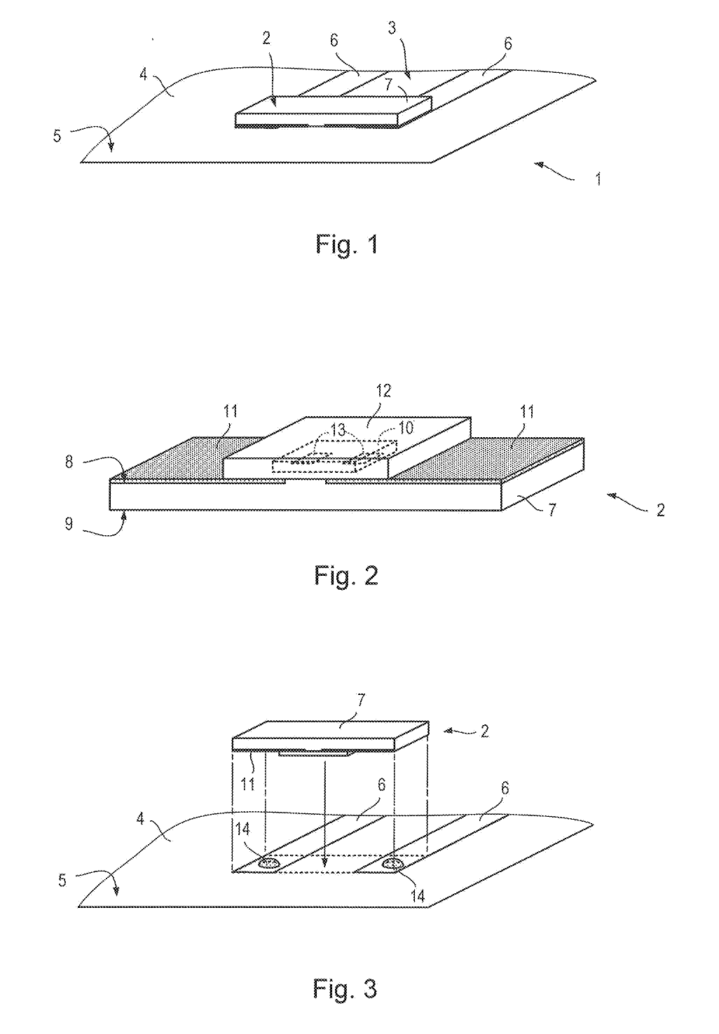

FIG. 1 shows part of flexible circuit board assembly 1.

Referring also to FIGS. 2 and 3, the circuit board assembly 1 comprises a module 2 and a circuit board 3. The circuit board 3 includes a flexible substrate 4 having a face 5 which supports a set of contact pads 6. The substrate 4 is formed from an insulating material, such as card, paper or plastic. The substrate 4 may take the form of a sheet of card or paper. The substrate 4 may be a laminate. In this example, only two contact pads 6 are shown. However, many contact pads 6, for example twenty or more, can be provided.

The contact pads 6 comprise conductive ink, such as silver-based conductive ink, and may be formed directly on the circuit board substrate 4. The contact pads 6 may be discrete pads which are connected to a set of conductive tracks (not shown). However, the contact pads 6 may be provided by sections or ends of conductive tracks. In some examples, the contact pads 6 may be provided by metallic foil, for example formed directly on the circuit board substrate 4. The contact pads 6 may have dimensions (e.g. width and/or length) of at least 100 μm. For example, the contact pads 6 have width of between 1 and 10 mm.

The module 2 comprises a flexible substrate 7, for example a sheet of card or plastic, having first and second faces 8, 9, a device 10 and a set of contact pads 11 supported on a first face 8 of the substrate 7. The module 2 may include a protective cover 12. The contact pads 11 comprise conductive ink, such as silver-based conductive ink, and may be formed directly on the module substrate 7. In some examples, the contact pads 11 may be provided by metallic foil. The contact pads 11 may have dimensions (e.g. width and/or length) of at least 100 μm. For example, the contact pads 11 have width of between 1 and 10 mm.

The device 10 includes a set of terminals 13, such as bond pads. Typically, terminals 13 have dimensions of about 100 μm. However, the terminals 13 can be bigger. In this example, a simple two-terminal device 10 is shown. However, the device 10 may have many terminals, for example 20 terminals or more. The terminals 13 are electrically connected to the contact pads 11. For example, each terminal 13 fully or partially overlaps a respective contact pad 11 and is attached using conductive glue, ink or tape (not shown).

Suitable modules and a method of making such modules are described in GB 2 472 047 A which is incorporated herein by reference.

Referring in particular to FIG. 3, the module 2 is attached to the circuit board 3 using conductive ink 14. The module 2 is mounted “face down”, i.e. flipped, on the circuit board 3 such that the device 10 is interposed between the substrates 4, 7.

The module contact pads 11 are electrically connected to the circuit board contact pads 6. For example, each module contact pad 11 fully or partially overlaps a respective circuit board pad 6 and is fixed using the conductive ink 14. The conductive ink 14 may include a non-conductive adhesive, such as polyvinyl acetate (PVA), silicone or epoxy resin, to increase adhesion. Conductive tape may be used instead of ink.

In some examples, the module 2 may be mounted “face up” on the circuit board 3 such that the module substrate 7 is interposed between the device 10 and the circuit board substrate 4. Electrical connection between the module contact pads 11 and the circuit board pads 6 can be achieved in one more different ways.

For example, opposite ends of the module 2 can be folded over and under the module 2 such that parts of the module contact pads 11 which are folded over face the circuit board 3.

Alternatively, a set of through-holes may be formed through the contact pads 11 and the module substrate 7, and filled with conductive ink. Another set of contact pads (not shown) can be formed on the second face 9 of the module substrate 7 and the conductive ink in the through-holes forms a connection between the two sets of module contact pads. However, the other set of contact pads can be omitted and ink used to fill the through-holes may also be used to provide electrical connections to the circuit board contact pads 6. The ink may be introduced after the module 2 and circuit board 3 have been aligned and brought into contact. In this case, ink can be drawn into the through-hole and between the module 2 and circuit board 3 by capillary action.

The module 2 and the circuit board assembly 1 can be assembled in substantially the same way, for example, using a continuous sheet process or other high-volume process which can be carried out using printing and/or converting processes (such that as described in GB 2 472 047 A). A flexographic printing process may be used. Pick-and-place robots can be used.

The module 2 and circuit board assembly 1 (including the module 2) can be assembled in the same plant and even in the same manufacturing line. This can help to simply manufacturing the circuit board assembly 1.

Furthermore, the same or similar types of materials can be used for the first and second substrates which can help to reduce mechanical stress.

It will be appreciated that many modifications may be made to the embodiments hereinbefore described.

The first and/or second substrate need not be formed of an insulating material. A substrate may comprise a conductive material (such as foil) coated with an insulating layer.

Conductive ink need not be used for contact pads and/or tracks. For example, de-metallised film may be used wherein a layer of metal (such as aluminium) which coats a plastic film (such as PET) is partially removed (i.e. de-metallised) by masking and then etching to leave electrodes and tracks.

The first and/or second substrate need not be flat. A substrate may be shaped (or “moulded”), for example to be embossed and/or to be contoured. Thus, the device can take the form of three-dimensional (i.e. non-flat) article, such as a computer mouse. A substrate may be formed from formable paper or card, such as Billerud FibreForm®.

The first and/or second substrates may have different outline shapes. For example, the substrates need not have straight edges, but can have curved edges. The first and/or second substrates may include slots, slits, holes (which are relatively small compared to the size of a substrate) and/or apertures (which are relatively large compared to the size of a substrate).

1. A circuit board assembly comprising:
a module which comprises a first flexible substrate and a device mounted on the first flexible substrate, and
a circuit board which comprises a second flexible substrate, wherein the module is mounted on the circuit board.

2. A circuit board assembly according to claim 1, wherein the device comprises a set of terminals, wherein the set of terminals are connected to a first set of contact pads provided on the first flexible substrate.

3. A circuit board assembly according to claim 2, wherein the first set of contact pads are connected to a second set of contact pads disposed on the second flexible substrate.

4. A circuit board assembly according to claim 2, wherein the first set of contact pads are connected to a third set of contact pads disposed on the first flexible substrate and the third set of contact pads are connected to the second set of contact pads disposed on the second flexible substrate.

5. A circuit board assembly according to claim 3, wherein second set of contact pads comprise a set of conductive tracks.

6. A circuit board assembly according to claim 1, wherein the device is interposed between the first and second flexible substrates.

7. A circuit board assembly according to claim 1, wherein the first flexible substrate is interposed between the device and the second flexible substrates.

8. A circuit board assembly according to claim 1, wherein the first flexible substrate comprises paper, card or cardboard.

9. A circuit board assembly according to claim 1, wherein the first flexible substrate comprises a plastic material.

10. A circuit board assembly according to claim 1, wherein the first flexible substrate comprises a laminate.

11. A circuit board assembly according to claim 1, wherein the first and second flexible substrates comprise substantially the same material(s).

12. A circuit board assembly according to claim 1, wherein the device is mounted to the first flexible substrate using conductive glue, conductive ink or conductive tape.

13. A circuit board assembly according to claim 1, wherein the first flexible substrate has an area of no more than 200 cm².

14. A circuit board assembly according to claim 1, wherein the module is mounted to the second flexible substrate using conductive glue, conductive ink or conductive tape.

15. A circuit board assembly according to claim 1, wherein the device comprises a semiconductor die.

16. A circuit board assembly according to claim 1, wherein the device comprises microcontroller.

17. A circuit board assembly according to claim 1, wherein the module comprises at least two devices mounted on the first flexible substrate.

18. A circuit board assembly according to claim 1, wherein the module comprises at least one further component mounted on a third flexible substrate mounted on the first flexible substrate.

19. A circuit board assembly according to claim 1, wherein the second flexible substrate comprises paper, card or cardboard.

20. A circuit board assembly according to claim 1, wherein the second flexible substrate comprises a plastic material.

21. A circuit board assembly according to claim 1, wherein the second flexible substrate comprises a laminate

22. A circuit board assembly according to claim 1, wherein the second flexible substrate has an area of at least 500 cm².

23. A circuit board assembly according to claim 1, wherein the second flexible substrate supports at least one capacitive touch switch and/or array of touch electrodes.

24. A circuit board assembly according to claim 1, wherein the circuit board assembly comprises a printed article or part of a printed article supporting printed indicia.

25. A method of manufacturing a circuit board assembly, the method comprising: mounting a module which comprises a first flexible substrate and a device mounted on the first flexible substrate module on a circuit board comprising a second flexible substrate.
